(19) United States
(12) Patent Application Publication
(10) Pub. No.: US 2022/0074070 A1
(43) Pub. Date: Mar. 10, 2022

(54) KIT OF PARTS COMPRISING A SYNTHETIC DIAMOND

(71) Applicant: FSF PTE LTD, Singapore (SG)

(72) Inventor: Naman Saurin Parikh, Dubai (AE)

(21) Appl. No.: 17/418,054

(22) PCT Filed: Dec. 23, 2019
(86) PCT No.: PCT/IB2019/061281

§ 371 Date: Jun. 24, 2021

(30) Foreign Application Priority Data
Dec. 27, 2018 (BE) 2018/5952

(51) Int. Cl. C30B 29/04; C30B 33/00

(52) U.S. Cl. CPC C30B 29/04; C30B 33/00

(57) ABSTRACT

Kit of parts comprising a synthetic diamond (17), which is accompanied by a slice (9) that was cut off the same original synthetic diamond (7), whereby both the slice (9) and the synthetic diamond 17) are engraved with an identical identification or with an identification which shows that the synthetic diamond (17) and the slice (9) belong together. The kit also comprises an accompanying numbered certificate (12) of authenticity, which refers to the identical identification engraved on the synthetic diamond (17) and the slice (9). The identical identification engraved on the synthetic diamond (17) and the slice (9) comprises the number of the accompanying certificate (12) of authenticity or refers to it.

### CROSS-REFERENCE TO RELATED APPLICATIONS

The present application is the National Phase entry of International Patent Application No. PCT/IB2019/061281 filed Dec. 23, 2019, the entire contents of which are hereby incorporated by reference into this application.

### TECHNICAL FIELD

The present disclosure relates to a method for identification of a synthetic diamond.

In particular, the present disclosure is intended for the identification and registration of a synthetic diamond.

### BACKGROUND

A synthetic diamond distinguishes itself from a natural diamond because it is the result of technological processes instead of geological processes for a natural diamond.

It is known that synthetic diamond can be manufactured by applying very high pressures and temperatures (High Pressure High Temperature or HPHT process) under laboratory conditions, but also by applying chemical vapour deposition (or CVD process) under laboratory conditions.

The HPHT process usually occurs in a reactor chamber in which temperatures and pressures can be generated which are designed to approximate the conditions under which natural diamond is formed in the earth.

Elements are added in a growth chamber that will stimulate the growth of diamonds: a carbon rich material such as diamond powder, a metal catalyst such as iron, nickel and cobalt and a small □ seed□ diamond that serves as mould on which the diamond will form. Once pressures of approximately 5 to 6 GP and temperatures of 1300° C. or more are achieved, the carbon rich material is absorbed by the metal catalyst to a certain saturation point. A temperature gradient in the growth chamber then allows carbon atoms to start crystallising on the seed diamond.

Depending on the desired size of the finished crystal, the process may take a couple of weeks to a couple of months. The growth form of the finished crystal is influenced by the temperature, but the predominant form is cubo-octahedral. No further processing is necessary before the diamond can be polished.

The CVD process usually occurs under strict conditions in a vacuum chamber and uses carbon rich gases such as hydrocarbons and methane. Typically, these gases are then brought to below atmospheric pressure and heated to 700-1200° C. where gas activation commences.

As the bonds in the gases begin to break, carbon atoms begin to attach to a substrate of diamond in the vacuum chamber, usually a square diamond crystal slice, also called “seed crystal”.

The growth rates vary, but after 40 to 60 days a diamond with jewellery quality is formed that has grown atom by atom. The finished diamond has a cubic form and often shows a black graphite edge which is a normal characteristic of the growth process.

To prepare the finished diamond for planning and polishing, lasers are used to cut the core out of the centre of the rough diamond. The graphite edge is hereby removed and the pure diamond cube remains, which will now be further processed to become a finished cut diamond.

In the past it was never possible to determine the accurate age of a natural diamond, as a natural diamond can be up to more than a billion years old.

However, the growth process of synthetic diamond allows us to document the growth process of the diamond down to the second from start to end, by the technology used for its production.

Synthetic diamond offers the advantage that it gives an ethical assurance of a diamond grown on request thereby eliminating environmental concerns in natural diamond mining.

Natural cut diamonds can be certified and their certificate number can be engraved in the diamond. However, it is impossible to specify the date of birth of the natural diamond, as this is not exactly known.

The purpose of the present disclosure is to provide a solution to the aforementioned and other disadvantages, by providing a method which allows the exact date of birth of a synthetic diamond to be shown, both on the synthetic diamond itself as on the accompanying certificate.

### SUMMARY

To this end, the present disclosure relates to a method for showing the exact date of birth of a synthetic diamond, which at least comprises the following steps:
cutting a slice off the synthetic diamond to be marked using a laser;
engraving at least the date of birth of the synthetic diamond and, optionally, additional information such as a number of an accompanying certificate of authenticity and a brand logo by a laser;
optionally engraving a personal message on the cut off slice and/or on the finished cut diamond derived from the remaining rough synthetic diamond;
incorporating the engraved slice of the synthetic diamond to be marked in a certificate of authenticity which bears the same number under a transparent window in the certificate;
engraving the same number of the accompanying certificate of authenticity on the finished cut diamond, derived from the remaining rough synthetic diamond, on its girdle.

The desired information relating to the synthetically manufactured diamond can be put on the certificate, such as the weight and the dimensions of the cut diamond, the cut, the production method, the history and place of manufacture and optical characteristics such as the clarity.

The engraved slice attached to the accompanying certificate of authenticity will often be too small to read with the naked eye. The slice is located behind a transparent window and if necessary can be read with a magnifying glass with a ×30 or ×50 lens.

As an alternative destination, the slice, with or without its certificate, can also be placed on the lid of the box, for example, in which the cut finished diamond is kept or offered.

Yet another alternative destination for the slice is that it can be incorporated in a jewel in the piece of jewellery itself or in an accompanying amulet which is worn together with the piece of jewellery for example.

### BRIEF DESCRIPTION OF THE DRAWINGS

In order to better explain the characteristics of the present disclosure, a few applications of the method for identification of a synthetic diamond according to the present disclosure are described hereinafter by way of an example, without any limiting nature, with reference to the accompanying drawings, wherein:

FIG. 1 schematically shows a perspective view of a synthetic diamond cubo-octahedral crystal;

FIG. 2 schematically shows a perspective view of the growth phases of a synthetic diamond cubic crystal;

FIG. 3 schematically shows a perspective view of cutting a synthetic diamond out of its surrounding black graphite;

FIG. 4 shows a perspective view of a synthetic diamond slice, cut according to the method of the present disclosure;

FIG. 5 shows a frontal view of a certificate of authenticity of a synthetic diamond according to the present disclosure;

FIG. 6 shows a frontal view of a piece of jewellery, provided with a synthetic diamond slice according to the present disclosure;

### DETAILED DESCRIPTION

FIG. 1 shows a perspective view of a synthetic diamond cubo-octahedral crystal 1, the predominant crystalline form of synthetic diamond manufactured with the HPHT process or high pressure and high temperature process. The process requires an extremely high pressure and takes a number of weeks to a number of months.

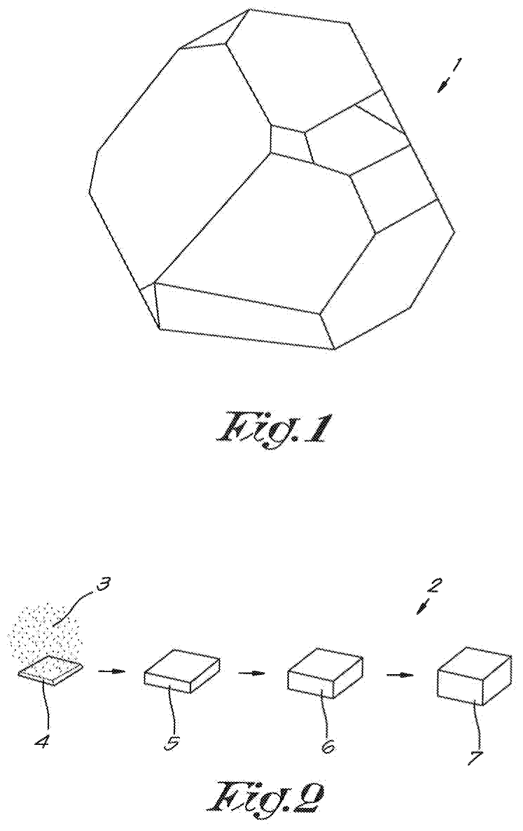

FIG. 2 shows the growth process 2 of a synthetic diamond manufactured according to the CVD process or Chemical Vapour Deposition process whereby gaseous carbon 3 is deposited on a seed crystal 4 at a pressure lower than atmospheric pressure and at a high temperature. From left to right the formation is shown of, in this case, a synthetic diamond cubic crystal, based on a synthetic diamond square seed crystal 4 on which gaseous carbon 3 is deposited in consecutive steps 5, 6 until for example a cubic crystal of a synthetic diamond cube 7.

The CVD process requires a growth period of approximately 40 to 60 days. As it grows, a ring of black graphite forms around the edge of the cubic crystal.

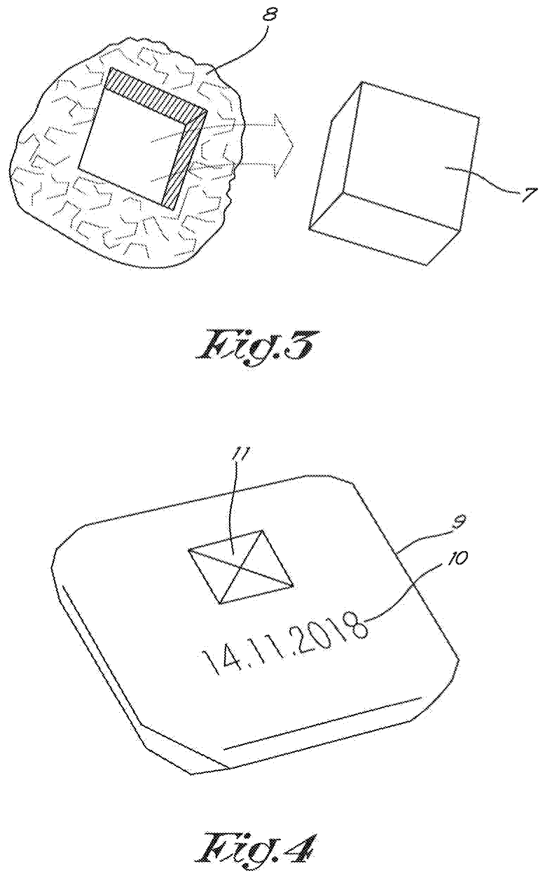

FIG. 3 shows how the cubic crystal of the synthetic diamond 7 is cut out of the surrounding ring of black graphite 8.

FIG. 4 shows a slice 9 cut off the synthetic diamond crystal 7 by a laser according to the method of the present disclosure. The slice 9 was cut off the synthetic diamond 7 to be identified. At least the date of birth 10 and, optionally, additional information 11 are engraved on the slice by a laser.

The additional information 11 can be a number of an accompanying certificate of authenticity and/or a brand logo or a personal message.

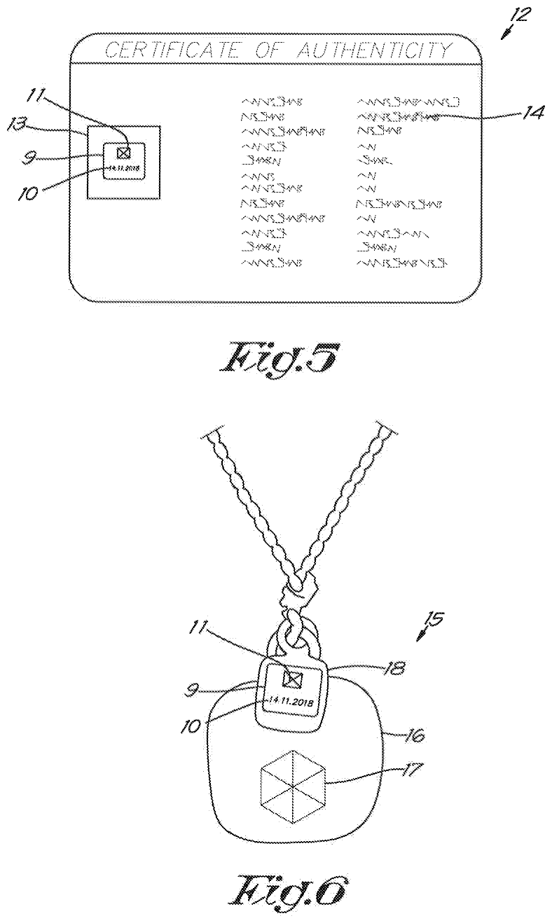

FIG. 5 shows a certificate of authenticity 12 of a synthetic diamond according to the present disclosure in which the slice 9 cut off the synthetic diamond 7 to be identified is integrated. The slice 9 can be placed behind a transparent window 13 such that the additional information 11 engraved on the slice 9 can be read at all times with the naked eye or with a magnifying glass of for example ×30 or ×50.

The certificate of authenticity 12 according to the present disclosure specifies all desired information 14 relating to the synthetically manufactured diamond, the slice 9 of which is attached to the certificate of authenticity 12 and the remaining section of which is cut further in a chosen cut.

The information 14 may comprise the weight and the dimensions of the cut diamond, the cut, the production method, the history and place of manufacture and optical characteristics such as the clarity. The number of the certificate of authenticity is specified on the certificate of authenticity 12 itself, but may also be engraved on the slice 9 located on the certificate of authenticity 12 and may also be engraved on the final cut diamond derived from the synthetic diamond. It is also possible to engrave a personal message on the slice 9 and/or on the final cut diamond itself and to specify this message in the desired information 14 on the certificate of authenticity 12.

FIG. 6 shows a piece of jewellery 15 in the form of a pendant 16 in which the final cut diamond 17 is processed. In this case the piece of jewellery is provided with an amulet 18 which contains the synthetic diamond slice 9, on which the date of birth of the final cut diamond 17 and the additional information can be read according to the present disclosure; The application of the method for marking and identifying a synthetic diamond according to the present disclosure is very simple and as follows.

A thin slice 9 of approximately 1 mm thickness is cut off a grown synthetic diamond 7 by a laser. On this slice 9 the date of birth 10 of the synthetic diamond 7 is engraved, i.e. the day on which the synthetic diamond 7 was obtained and additional information 11 about the synthetic diamond 7 such as the number of an accompanying certificate of authenticity 12 and/or a brand logo or brand name of the producer and/or place of production or also a personal message.

The slice 9 can be included in an accompanying certificate of authenticity 12 whereby the information on the slice 9 can be read through a transparent window 13, possibly with a magnifying glass. The certificate of authenticity 12 may bear additional information, such as the weight and the dimensions of the final cut diamond 17, its cut, the history and place of manufacture and optical characteristics such as the clarity.

The number of the certificate of authenticity may also be engraved on the slice 9 and may also be engraved on the final cut diamond 17, such that it is clear they belong together. The relationship between the slice 9 and the cut diamond 17 may also be indicated by engraving a personal message on the slice 9 and on the final cut diamond 17.

Thus the slice 9 and the accompanying final cut diamond 17 may be sold or offered together, for example in the form of a box containing the cut diamond the lid of which contains the slice 9.

Thus the slice 9 and the accompanying final cut diamond 17 may also be worn together in the form of a piece of jewellery 15 with the cut diamond 17, to which an amulet 18 with the slice 9 is attached for example.

An advantage of this present disclosure is that it allows the usual history from diamond mine to market for a natural diamond to be mirrored in a synthetic diamond history from manufacture to finished market product, whereby an exact date of birth of the synthetic diamond can be provided.

The exact date of birth of the synthetic diamond 7 is the date on which the completed rough synthetic diamond 7 comes out of the machine with which it is manufactured. This synthetic diamond 7 can be chosen to mark an event that takes place on exactly the same date of birth, for example a birth or a wedding, or on the same date in another year such as an anniversary, or on a date associated with the date of birth of the synthetic diamond 7, for example a birthday. The date of the event and the description of the event may also be included in the accompanying numbered certificate of authenticity 12 included in the kit of parts.

This allows a buyer to choose a synthetic diamond 7 with a desired date of birth from a series of available synthetic diamonds 7 which each bear an exact date of birth. This is only possible for a synthetic diamond 7, the exact date of birth of which is known, unlike natural diamonds the exact date of birth of which will remain unknown.

The present disclosure is not limited to the embodiments described as an example and shown in the drawings, but such a method for showing the exact date of birth of a synthetic diamond can be realised according to different variants without departing from the scope of the present disclosure, as is defined in the following claims.

1. Use of a laser to cut a slice of a synthetic diamond and to engrave both the slice and a remaining part the synthetic diamond, wherein that both the slice and the remaining part are engraved with a birthday of the synthetic diamond and with a number of a certificate of authenticity, and in that the engraved slice of the synthetic diamond is incorporated in the certificate of authenticity under a transparent window in the certificate of authenticity, and in that the number of the certificate of authenticity is engraved on a final cut diamond, derived from the remaining part of the synthetic diamond, such that it is clear that the engraved slice and the final cut diamond belong together.

2. The use of the laser according to claim 1, wherein both the slice and the remaining part are engraved with additional information.

3. The use of the laser according to claim 2, wherein the additional information comprises a brand logo of the synthetic diamond.

4. The use of the laser according to claim 2, wherein the additional information comprises a personal message.

5. The use of the laser according to claim 1, wherein the number of the certificate of authenticity is engraved on a girdle of the final cut diamond.

6. The use of the laser according to claim 1, wherein all desired information relating to the synthetic diamond is mentioned on the certificate of authenticity, the desired information includes at least weight and dimensions of the final cut diamond, diamond cut, production method, history and place of production and optical characteristics such as clarity.

7. The use of the laser according to claim 1, wherein the slice, with or without being placed in the certificate of authenticity, is put on a lid of a box in which the final cut diamond is kept or offered.

8. The use of the laser according to claim 1, wherein the slice is incorporated in a jewel together with the final cut diamond itself or in a linked amulet that is worn together with the jewel.

9. A method for identification of a synthetic diamond comprising:
cutting off a slice of the synthetic diamond;
engraving the slice and a remaining part of the synthetic diamond with a birthday of the synthetic diamond and a number of a certificate of authenticity; and
incorporating the engraved slice of the synthetic diamond under a transparent window in the certificate of authenticity,
wherein the number of the certificate of authenticity is engraved on a final cut diamond derived from the remaining part of the synthetic diamond so as to correspond the engraved slice to the final cut diamond.

10. The method according to claim 9, wherein both the slice and the remaining part are engraved with additional information.

11. The method according to claim 10, wherein the additional information comprises a brand logo of the synthetic diamond.

12. The method according to claim 10, wherein the additional information comprises a personal message.

13. The method according to claim 9, wherein the number of the certificate of authenticity is engraved on a girdle of the final cut diamond.

14. The method according to claim 9, wherein all desired information relating to the synthetic diamond is mentioned on the certificate of authenticity, the desired information includes at least weight and dimensions of the final cut diamond, diamond cut, production method, history and place of production and optical characteristics such as clarity.

15. The method according to claim 9, wherein the slice, with or without being placed in the certificate of authenticity, is put on a lid of a box in which the final cut diamond is kept or offered.

16. The method according to claim 9, wherein the slice is incorporated in a jewel together with the final cut diamond itself or in a linked amulet that is worn together with the jewel.

17. The method according to claim 9, wherein the slice is cut off of the synthetic diamond by a laser.

18. The method of according to claim 9, wherein the slice of the synthetic diamond and the remaining part of the synthetic diamond are engraved by a laser.
